(19) United States
(12) Patent Application Publication
(10) Pub. No.: US 2018/0108545 A1
(43) Pub. Date: Apr. 19, 2018

(54) WET ETCHING DEVICE AND EXPLOSION PREVENTION METHOD THEREOF

(71) Applicant: Shenzhen China Star Optoelectronics Technology Co., Ltd., Shenzhen City (CN)

(72) Inventor: Jia Li, Shenzhen City (CN)

(21) Appl. No.: 15/117,450

(22) PCT Filed: Jun. 20, 2016
(86) PCT No.: PCT/CN2016/086435

§ 371 Date: Aug. 9, 2016

(30) Foreign Application Priority Data
May 10, 2016 (CN) 201610307235.4

(51) Int. Cl. H01L 21/67; G02F 1/13; C23F 1/00

(52) U.S. Cl. CPC H01L 21/67023; H01L 21/67248; H01L 27/124; C23F 1/00; G02F 1/1303

(57) ABSTRACT

The present invention provides a wet etching device and an explosion prevention method thereof. The heater (22) is utilized to monitor the temperature in the liquid storage tank (2). When the temperature in the liquid storage tank (2) reaches the preset upper temperature limit, the control device (23) automatically deactivates the heater (22), and activates the chamber cleaning device (11) to spray the cleaning water. After washing the reaction chamber (1), the cleaning water flows back in the liquid storage tank (2) and neutralizes the etching solution in the liquid storage tank (2) to lower the temperature in the liquid storage tank (2). It can effectively monitor and reduce the temperature in the liquid storage tank (2) to prevent that the liquid storage tank (2) is overheated and explodes, to ensure the production safety and raise the production utilization rate.

### FIELD OF THE INVENTION

The present invention relates to a semiconductor manufacture technology field, and more particularly to a wet etching device and an explosion prevention method thereof.

### BACKGROUND OF THE INVENTION

The Liquid Crystal Display (LCD) possesses advantages of thin body, power saving and no radiation to be widely used in many application scope, such as LCD TV, mobile phone, personal digital assistant (PDA), digital camera, notebook, laptop, and dominates the flat panel display field.

As the Thin Film Transistor-Liquid Crystal Display (TFT-LCD) is gradually developed to the directions of super large size, high drive frequency and high resolution. It becomes more and more important how to effectively decrease the resistance and the parasitic capacitor of the panel conductive line. As manufacturing the Thin Film Transistor-Liquid Crystal Display, the high quality conductive line manufacture skill has already becomes the key of determining the properties of the thin film transistor assembly and the panel.

The metal conductive line in the thin film transistor array substrate is manufactured by implementing etching process to the metal layer, which is sputtered on the thin film transistor array substrate. The regular metal conductive line applied in the thin film transistor array substrate is the aluminum conductive line. With the development trend and requirement of the large scale high resolution and drive frequency high speed of the liquid crystal display terminal of the television, the technician of the liquid crystal display field has to face the resistance or capacitance time delay issues caused by the resistors in the thin film transistor array substrate. The aluminum conductive line has higher resistivity so that the pixel electrode of the thin film transistor array substrate cannot be fully charged. With the wide application of the high frequency addressing liquid crystal display, this phenomenon is more obvious.

Because the copper conductive line manufacture process has advantages of low resistance and low delay phenomenon, it can make the signal addressing speed faster, the scan line more clustered, and the display quality fresher. After the copper manufacture process yield is promoted, the production cost of the high quality panel of ultra-high resolution can have change to be decreased in advance; the aluminum has commonly replaced with copper for the 4 conductive lines in the large scale thin film transistor liquid crystal display panel. In the present copper conductive line etching process, the commonly utilized etching solution is oxydol series (H₂O₂). There will be the following issues as the etching solution is used: with the continuation of the etched process, the copper ion concentration of the etching solution keeps going up. The H₂O₂ will have chemical change of acceleration decomposition under the function of the copper ion, and the reaction process is:

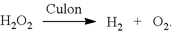

Furthermore, with the progress of the Cu-interconnection etching process, the copper ion concentration of the etching liquid keeps increasing. The decomposition rate of the H₂O₂ gets faster and faster. The decomposition rate of the H₂O₂ will rapidly increase and generates a mass of gas which can easily cause the explosion of the apparatus with extremely high possibility.

### SUMMARY OF THE INVENTION

An objective of the present invention is to provide a wet etching device, which can effectively monitor and lower the temperature in the liquid storage tank in time to prevent that the temperature in the liquid storage tank is too high and explosion happens to ensure the production safety and raise the production utilization rate.

Another objective of the present invention is to provide an explosion prevention method of a wet etching device, which can effectively monitor and lower the temperature in the liquid storage tank in time to prevent that the temperature in the liquid storage tank is too high and explosion happens to ensure the production safety and raise the production utilization rate.

Fore realizing the aforesaid objectives, the present invention first provides a wet etching device, comprising: an etching reaction chamber, a chamber cleaning device located in the etching reaction chamber, a liquid storage tank connected to the etching reaction chamber, a heater located in the liquid storage tank, a liquid drain pipe located at the bottom of the liquid storage tank and connected with the liquid storage tank, an overflow port located at an upper surface of the liquid storage tank, an overflow pipe connected with the overflow port and the liquid drain pipe and a control device electrically connected with the chamber cleaning device and the heater;

where the liquid storage tank stores etching solution, and the heater heats the etching solution and monitors a temperature in the liquid storage tank, and the control device deactivates the heater as the temperature in the liquid storage tank reaches a preset upper temperature limit, and activates the chamber cleaning device to spray cleaning water to lower the temperature in the liquid storage tank.

The wet etching device is employed for a copper metal etching process.

The cleaning water is deionized water.

The etching liquid is oxydol series etching liquid.

The control device is a PLC.

The present invention further provides an explosion prevention method of a wet etching device, comprising steps of:

step 1, providing a wet etching device, comprising: an etching reaction chamber, a chamber cleaning device located in the etching reaction chamber, a liquid storage tank connected to the etching reaction chamber, a heater located in the liquid storage tank, a liquid drain pipe located at the bottom of the liquid storage tank and connected with the liquid storage tank, an overflow port located at an upper surface of the liquid storage tank, an overflow pipe connected with the overflow port and the liquid drain pipe and a control device electrically connected with the chamber cleaning device and the heater;

step 2, storing the etching solution in the liquid storage tank, and heating the etching solution with the heater, and meanwhile, monitoring a temperature in the liquid storage tank and transmitting temperature data to the control device with the heater;

step 3, determining whether a present temperature in the liquid storage tank reaches a preset upper temperature limit or not with the control device, and if the present temperature in the liquid storage tank reaches the preset upper temperature limit, deactivating the heater, and activating the chamber cleaning device to spray cleaning water, wherein after washing the etching reaction chamber, the cleaning water flows back in the liquid storage tank and neutralizes the etching solution in the liquid storage tank to lower the temperature in the liquid storage tank to prevent that the liquid storage tank is overheated and explodes.

The explosion prevention method of the wet etching device is employed for a copper metal etching process.

The cleaning water in the step 3 is deionized water.

The etching solution in the step 2 is oxydol series etching solution.

The control device in the step 1 is a PLC.

The present invention further provides a wet etching device, comprising: an etching reaction chamber, a chamber cleaning device located in the etching reaction chamber, a liquid storage tank connected to the etching reaction chamber, a heater located in the liquid storage tank, a liquid drain pipe located at the bottom of the liquid storage tank and connected with the liquid storage tank, an overflow port located at an upper surface of the liquid storage tank, an overflow pipe connected with the overflow port and the liquid drain pipe and a control device electrically connected with the chamber cleaning device and the heater;

where the liquid storage tank stores etching solution, and the heater heats the etching solution and monitors a temperature in the liquid storage tank, and the control device deactivates the heater as the temperature in the liquid storage tank reaches a preset upper temperature limit, and activates the chamber cleaning device to spray cleaning water to lower the temperature in the liquid storage tank;

wherein the wet etching device is employed for a copper metal etching process;

the cleaning water is deionized water.

The benefits of the present invention are: the present invention provides a wet etching device. The heater is utilized to monitor the temperature in the liquid storage tank. When the temperature in the liquid storage tank reaches the preset upper temperature limit, the control device automatically deactivates the heater, and activates the chamber cleaning device to spray the cleaning water. After washing the reaction chamber, the cleaning water flows back in the liquid storage tank and neutralizes the etching solution in the liquid storage tank to lower the temperature in the liquid storage tank. It can effectively monitor and reduce the temperature in the liquid storage tank to prevent that the liquid storage tank is overheated and explodes, to ensure the production safety and raise the production utilization rate. Particularly, it is suitable for the copper metal etching process in which the oxydol series etching solution is utilized for etching, which can effectively prevent the explosion due to the oxydol decomposition in the manufacture process. The explosion prevention method of the wet etching device provided by the present invention can effectively monitor and lower the temperature in the liquid storage tank in time to prevent that the temperature in the liquid storage tank is too high and explosion happens to ensure the production safety and raise the production utilization rate.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a structure diagram of a wet etching device according to the present invention;

FIG. 2 is a flowchart of an explosion prevention method of the wet etching device according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

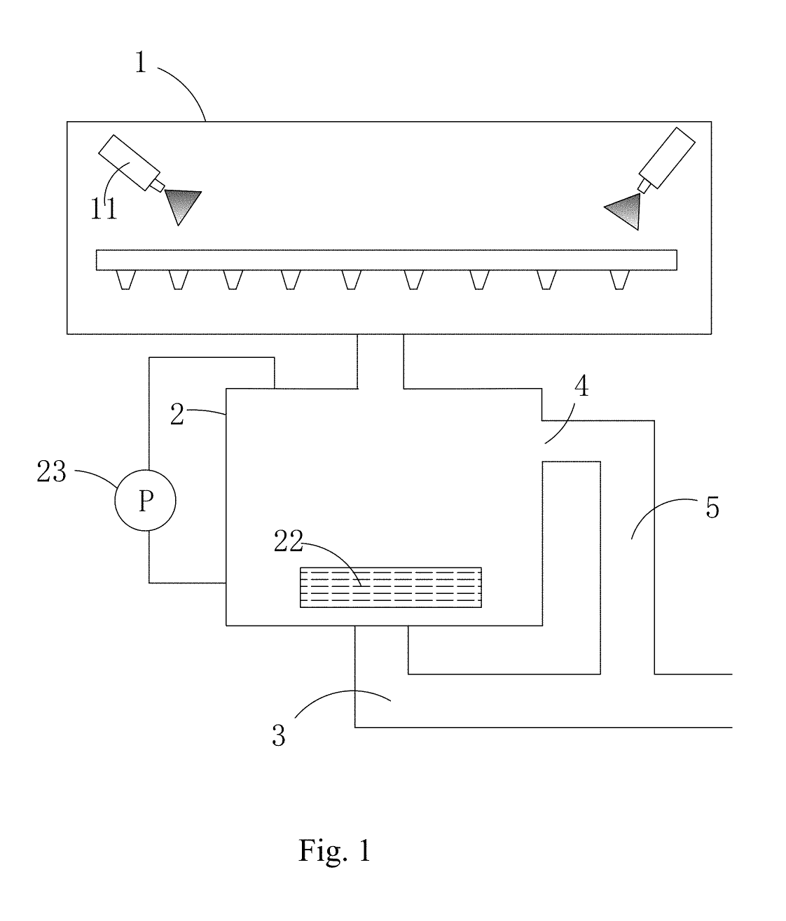

Please refer to FIG. 1. The present invention provides a wet etching device, comprising: an etching reaction chamber 1, a chamber cleaning device 11 located in the etching reaction chamber 1, a liquid storage tank 2 connected to the etching reaction chamber 1, a heater 22 located in the liquid storage tank 2, a liquid drain pipe 3 located at the bottom of the liquid storage tank 2 and connected with the liquid storage tank 2, an overflow port 4 located at an upper surface of the liquid storage tank 2, an overflow pipe 5 connected with the overflow port 4 and the liquid drain pipe 3 and a control device 23 electrically connected with the chamber cleaning device 11 and the heater 22.

Specifically, the liquid storage tank 2 is employed to store the etching solution. The heater 22 is employed to heat the etching solution and monitor the temperature in the liquid storage tank 2. The control device 23 is employed to deactivate the heater 22 as the temperature in the liquid storage tank 2 reaches a preset upper temperature limit, and to activate the chamber cleaning device 11, and the chamber cleaning device 11 is employed to spray cleaning water to lower the temperature in the liquid storage tank 2. The etching reaction chamber 1 is employed for performing the etching reaction. The overflow port 4 and the overflow pipe 5 are employed to drain the etching solution in time to prevent the overflow when the etching solution in the liquid storage tank 2 is too much. The liquid drain pipe 3 is employed to eliminate the solution in the liquid storage tank 2.

Specifically, the wet etching method is suitable for the wet etching process in which the temperature of liquid storage tank is too high to result in the explosion in the wet etching process, such as the copper metal etching process in which the oxydol series etching solution is utilized for etching.

Preferably, the cleaning water sprayed by the chamber cleaning device 11 is deionized water (DIW). The deionized water can effectively clean the impurities, such as colloid and suspended matter to neutralize the overheated etching solution and can effectively lower the temperature in the liquid storage tank 2.

Specifically, the control device 23 can be a Programmable Logic Controller (PLC). The PLC can achieve the automatic control of the heater 22 and the chamber cleaning device 11 and simplify the operation.

Specifically, after the wet etching device detects that the temperature in the liquid storage tank 2 is too high, the working procedure of cooling is: the control device 23 automatically deactivates the heater 22, and automatically activates the chamber cleaning device 11 to spray the deionized water to wash the entire etching reaction chamber 1, and the residual etching solution in the etching reaction chamber 1 flows back in the liquid storage tank 2 with the deionized water along the pipe line, and the deionized water neutralizes the overheated etching solution in the liquid storage tank 2 so that the temperature in the liquid storage tank 2 gradually decreases, and the liquid level in the liquid storage tank 2 is gradually raised, and the solution exceeding the position of the overflow port 4 is drained from the overflow pipe 5, and as the temperature of the liquid storage tank 2 is lowered to the room temperature, the control device 23 automatically deactivates the chamber cleaning device 11, and the drain pipe at the bottom of the liquid storage tank 2 is opened to drain all the remained solution to effectively prevent that the temperature of the liquid storage tank 2 is too high and causes the explosion.

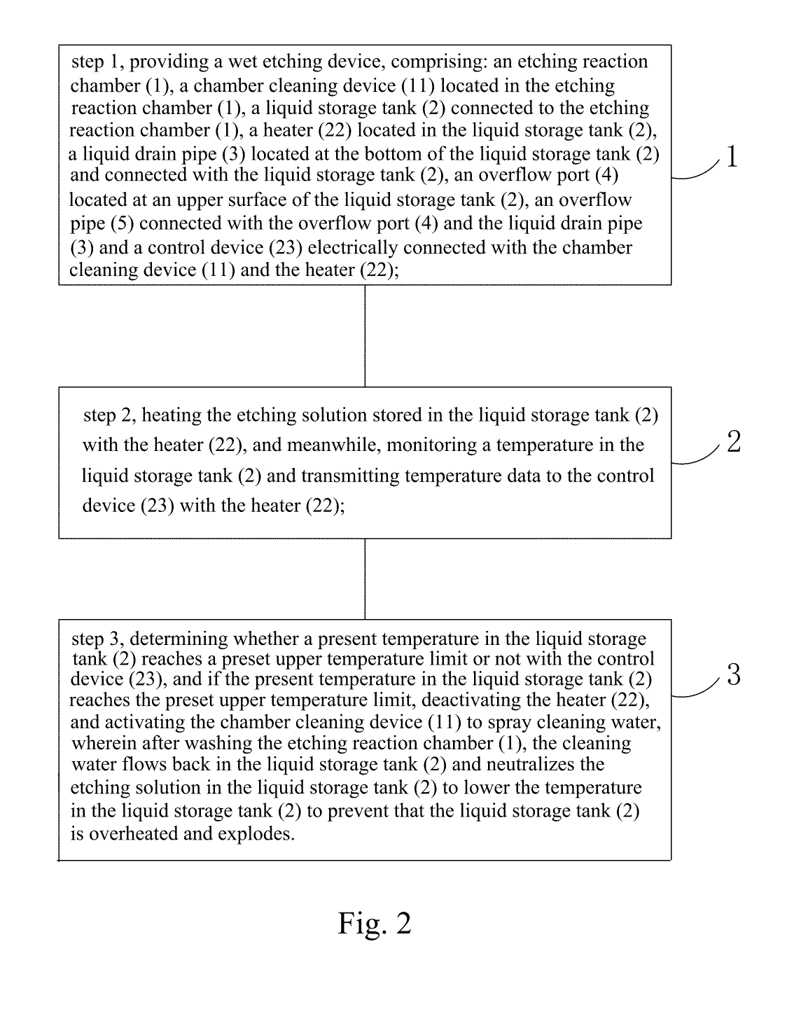

Please refer to FIG. 2. Based on the aforesaid wet etching device, the present invention further provides an explosion prevention method of a wet etching device, comprising steps of:

step 1, providing a wet etching device, comprising: an etching reaction chamber 1, a chamber cleaning device 11 located in the etching reaction chamber 1, a liquid storage tank 2 connected to the etching reaction chamber 1, a heater 22 located in the liquid storage tank 2, a liquid drain pipe 3 located at the bottom of the liquid storage tank 2 and connected with the liquid storage tank 2, an overflow port 4 located at an upper surface of the liquid storage tank 2, an overflow pipe 5 connected with the overflow port 4 and the liquid drain pipe 3 and a control device 23 electrically connected with the chamber cleaning device 11 and the heater 22.

Specifically, the liquid storage tank 2 is employed to store the etching solution. The etching reaction chamber 1 is employed for performing the etching reaction. The overflow port 4 and the overflow pipe 5 are employed to drain the etching solution in time to prevent the overflow when the etching solution in the liquid storage tank 2 is too much. The liquid drain pipe 3 is employed to eliminate the solution in the liquid storage tank 2.

Preferably, the control device 23 is a PLC.

step 2, heating the etching solution stored in the liquid storage tank 2 with the heater 22, and meanwhile, monitoring a temperature in the liquid storage tank 2 and transmitting temperature data to the control device 23 with the heater 22;

step 3, determining whether a present temperature in the liquid storage tank 2 reaches a preset upper temperature limit or not with the control device 23, and if the present temperature in the liquid storage tank 2 reaches the preset upper temperature limit, deactivating the heater 22, and activating the chamber cleaning device 11 to spray cleaning water, wherein after washing the etching reaction chamber 1, the cleaning water flows back in the liquid storage tank 2 and neutralizes the etching solution in the liquid storage tank 2 to lower the temperature in the liquid storage tank 2 to prevent that the liquid storage tank 2 is overheated and explodes.

Specifically, the wet etching method is suitable for the wet etching process in which the temperature of liquid storage tank is too high to result in the explosion in the wet etching process, such as the copper metal etching process in which the oxydol series etching solution is utilized for etching.

Preferably, the cleaning water sprayed by the chamber cleaning device 11 is deionized water. The deionized water can effectively clean the impurities, such as colloid and suspended matter to neutralize the overheated etching solution and can effectively lower the temperature in the liquid storage tank 2.

Furthermore, the detail procedure of the step 3 is: the control device 23 automatically deactivates the heater 22, and automatically activates the chamber cleaning device 11 to spray the deionized water to wash the entire etching reaction chamber 1, and the residual etching solution in the etching reaction chamber 1 flows back in the liquid storage tank 2 with the deionized water along the pipe line, and the deionized water neutralizes the overheated etching solution in the liquid storage tank 2 so that the temperature in the liquid storage tank 2 gradually decreases, and the liquid level in the liquid storage tank 2 is gradually raised, and the solution exceeding the position of the overflow port 4 is drained from the overflow pipe 5, and as the temperature of the liquid storage tank 2 is lowered to the room temperature, the control device 23 automatically deactivates the chamber cleaning device 11, and the drain pipe at the bottom of the liquid storage tank 2 is opened to drain all the remained solution to effectively prevent that the temperature of the liquid storage tank 2 is too high and causes the explosion.

In conclusion, the present invention provides a wet etching device. The heater is utilized to monitor the temperature in the liquid storage tank. When the temperature in the liquid storage tank reaches the preset upper temperature limit, the control device automatically deactivates the heater, and activates the chamber cleaning device to spray the cleaning water. After washing the reaction chamber, the cleaning water flows back in the liquid storage tank and neutralizes the etching solution in the liquid storage tank to lower the temperature in the liquid storage tank. It can effectively monitor and reduce the temperature in the liquid storage tank to prevent that the liquid storage tank is overheated and explodes, to ensure the production safety and raise the production utilization rate. Particularly, it is suitable for the copper metal etching process in which the oxydol series etching solution is utilized for etching, which can effectively prevent the explosion due to the oxydol decomposition in the manufacture process. The explosion prevention method of the wet etching device provided by the present invention can effectively monitor and lower the temperature in the liquid storage tank in time to prevent that the temperature in the liquid storage tank is too high and explosion happens to ensure the production safety and raise the production utilization rate.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A wet etching device, comprising: an etching reaction chamber, a chamber cleaning device located in the etching reaction chamber, a liquid storage tank connected to the etching reaction chamber, a heater located in the liquid storage tank, a liquid drain pipe located at the bottom of the liquid storage tank and connected with the liquid storage tank, an overflow port located at an upper surface of the liquid storage tank, an overflow pipe connected with the overflow port and the liquid drain pipe and a control device electrically connected with the chamber cleaning device and the heater;
where the liquid storage tank stores etching solution, and the heater heats the etching solution and monitors a temperature in the liquid storage tank, and the control device deactivates the heater as the temperature in the liquid storage tank reaches a preset upper temperature limit, and activates the chamber cleaning device to spray cleaning water to lower the temperature in the liquid storage tank.

2. The wet etching device according to claim 1, wherein the wet etching device is employed for a copper metal etching process.

3. The wet etching device according to claim 2, wherein the cleaning water is deionized water.

4. The wet etching device according to claim 2, wherein the etching solution is oxydol series etching solution.

5. The wet etching device according to claim 1, wherein the control device is a PLC.

6. An explosion prevention method of a wet etching device, comprising steps of:
step 1, providing a wet etching device, comprising: an etching reaction chamber, a chamber cleaning device located in the etching reaction chamber, a liquid storage tank connected to the etching reaction chamber, a heater located in the liquid storage tank, a liquid drain pipe located at the bottom of the liquid storage tank and connected with the liquid storage tank, an overflow port located at an upper surface of the liquid storage tank, an overflow pipe connected with the overflow port and the liquid drain pipe and a control device electrically connected with the chamber cleaning device and the heater;
step 2, heating the etching solution stored in the liquid storage tank with the heater, and meanwhile, monitoring a temperature in the liquid storage tank and transmitting temperature data to the control device with the heater;
step 3, determining whether a present temperature in the liquid storage tank reaches a preset upper temperature limit or not with the control device, and if the present temperature in the liquid storage tank reaches the preset upper temperature limit, deactivating the heater, and activating the chamber cleaning device to spray cleaning water, wherein after washing the etching reaction chamber, the cleaning water flows back in the liquid storage tank and neutralizes the etching solution in the liquid storage tank to lower the temperature in the liquid storage tank to prevent that the liquid storage tank is overheated and explodes.

7. The explosion prevention method of the wet etching device according to claim 6, wherein the explosion prevention method of the wet etching device is employed for a copper metal etching process.

8. The explosion prevention method of the wet etching device according to claim 7, wherein the cleaning water in the step 3 is deionized water.

9. The explosion prevention method of the wet etching device according to claim 7, wherein the etching solution in the step 2 is oxydol series etching solution.

10. The explosion prevention method of the wet etching device according to claim 6, wherein the control device in the step 1 is a PLC.

11. A wet etching device, comprising: an etching reaction chamber, a chamber cleaning device located in the etching reaction chamber, a liquid storage tank connected to the etching reaction chamber, a heater located in the liquid storage tank, a liquid drain pipe located at the bottom of the liquid storage tank and connected with the liquid storage tank, an overflow port located at an upper surface of the liquid storage tank, an overflow pipe connected with the overflow port and the liquid drain pipe and a control device electrically connected with the chamber cleaning device and the heater;
where the liquid storage tank stores etching solution, and the heater heats the etching solution and monitors a temperature in the liquid storage tank, and the control device deactivates the heater as the temperature in the liquid storage tank reaches a preset upper temperature limit, and activates the chamber cleaning device to spray cleaning water to lower the temperature in the liquid storage tank;
wherein the wet etching device is employed for a copper metal etching process;
the cleaning water is deionized water.

12. The wet etching device according to claim 11, wherein the etching solution is oxydol series etching solution.

13. The wet etching device according to claim 11, wherein the control device is a PLC.
